(19) United States
(12) Patent Application Publication
(10) Pub. No.: US 2026/0362898 A1
(43) Pub. Date: Nov. 12, 2026

(54) DISPLAY PANEL AND DISPLAY DEVICE

(71) Applicant: Hubei Yangtze Industrial Innovation Center Of Advanced Display Co, Rd,, Wuhan (CN)

(72) Inventors: Shuai ZHENG, Wuhan (CN); Maoqing Zhou, Wuhan (CN)

(73) Assignee: Hubei Yangtze Industrial Innovation Center Of Advanced Display Co., Ltd., Wuhan (CN)

(21) Appl. No.: 19/426,025

(22) Filed: Dec. 18, 2025

(30) Foreign Application Priority Data
May 12, 2025 (CN) 202510607842.1

(51) Int. Cl. H10K 59/121; G02F 1/1362; G02F 1/1368; G09G 3/3233; G09G 3/36; H10K 59/131

(52) U.S. Cl. CPC H10K 59/1213; G02F 1/13624; G02F 1/13629; G02F 1/1368; G09G 3/3233; G09G 3/3648; H10K 59/1315; G09G 2310/08; G09G 2320/0233; G09G 2320/0247

(57) ABSTRACT

Provide are a display panel and a display device. A pixel circuit in the display panel includes a driving transistor and a first switching transistor, a control portion of the driving transistor being electrically connected to a first electrode of the first switching transistor, and a control portion of the first switching transistor comprising first and second control portions. A first conductive layer is disposed on a side of the substrate and includes a first conductor portion. An active layer is disposed on a side of the first conductive layer facing away from the substrate and includes a first channel portion, an orthographic projection of the first channel portion on the substrate overlaps an orthographic projection of the first control portion on the substrate, and the first channel portion is electrically connected to the first electrode of the first switching transistor.

### CROSS-REFERENCE TO RELATED APPLICATIONS

This application claims priority to Chinese Patent Application No. 202510607842.1, filed on May 12, 2025, which is hereby incorporated by reference in its entirety.

### TECHNICAL FIELD

The present disclosure relates to the technical field of display apparatus, and in particular, to a display panel and a display device.

### BACKGROUND

With the continuous development of display technology, such as the liquid crystal display (LCD) and the organic light-emitting diode (OLED) display, display panels have been widely used in various industries. However, a flicker problem remains unresolved on display panels in practical use, which degrades the user's experience.

### SUMMARY

In a first aspect, some embodiments of the present disclosure provide a display panel. The display panel includes a sub-pixel and a pixel circuit configured to drive and control the sub-pixel, the pixel circuit including a driving transistor and a first switching transistor, a control portion of the driving transistor being electrically connected to a first electrode of the first switching transistor, and control portions of the first switching transistor including a first control portion and a second control portion. The display panel includes a substrate, a first conductive layer, an active layer, and a second conductive layer. The first conductive layer is disposed on a side of the substrate and includes a first conductor portion. The active layer is disposed on a side of the first conductive layer facing away from the substrate and includes a first channel portion, an orthographic projection of the first channel portion on the substrate overlapping an orthographic projection of the first control portion on the substrate, and the first channel portion being electrically connected to the first electrode of the first switching transistor. The second conductive layer is disposed on a side of the active layer facing away from the substrate, the first control portion and the second control portion being disposed in the second conductive layer. An orthographic projection of the first conductor portion on the substrate overlaps the orthographic projection of the first channel portion on the substrate, and the first conductor portion is configured to receive a variable voltage signal.

In a second aspect, some embodiments of the present disclosure provide a display device, and the display device includes the display panel provided in any one of the above embodiments.

Embodiments of the present disclosure provide the display panel and the display device. The first conductive layer is provided in the display panel, the first conductive layer is located at an inner side of the active layer away from the second conductive layer and includes the first conductor portion, and the orthographic projection of the first conductor portion on the substrate overlaps the orthographic projection of the first channel portion on the substrate. On this basis, when the first switching transistor is switched from an on state to an off state, an electrical conductivity of the first channel portion can be changed by transmitting a specific signal voltage to the first conductor portion, thereby adjusting a degree of the current leakage between an intermediate node of the first switching transistor and a first node to improve the flicker problem of the display picture.

### BRIEF DESCRIPTION OF THE DRAWINGS

To describe the technical solutions in the embodiments of the present disclosure more clearly, the following briefly introduces the accompanying drawings required for describing the embodiments of the present disclosure. Those of ordinary skill in the art may still derive other drawings from these accompanying drawings without creative efforts.

FIG. 1 is a layout schematic diagram of a pixel circuit in a display panel according to some embodiments of the present disclosure;

FIG. 2A to FIG. 2D are schematic diagrams of a partial structure of a first switching transistor in a display panel and layer structures in the first switching transistor according to some embodiments of the present disclosure;

FIG. 3 is a cross-sectional view along line A-A in FIG. 2A according to some embodiments of the present disclosure;

FIG. 4 is a simplified schematic diagram of a pixel circuit in a display panel according to some embodiments of the present disclosure;

FIG. 5 is a timing sequence of a pixel circuit in a display panel according to some embodiments of the present disclosure;

FIG. 6 is another layout schematic diagram of a pixel circuit in a display panel according to some embodiments of the present disclosure;

FIG. 7 is another partial schematic diagram of a first switching transistor in a display panel according to some embodiments of the present disclosure;

FIG. 8 is another layout schematic diagram of a pixel circuit in a display panel according to some embodiments of the present disclosure;

FIG. 9 is another schematic diagram of a first conductive layer in a display panel according to some embodiments of the present disclosure;

FIG. 10 is a partial layout schematic diagram of a display panel according to some embodiments of the present disclosure;

FIG. 11 is a schematic diagram of an active layer in a display panel according to some embodiments of the present disclosure;

FIG. 12 is another layout schematic diagram of a pixel circuit in a display panel according to some embodiments of the present disclosure;

FIG. 13 is another layout schematic diagram of a pixel circuit in a display panel according to some embodiments of the present disclosure;

FIG. 14 is another layout schematic diagram of a pixel circuit in a display panel according to some embodiments of the present disclosure;

FIG. 15 is a schematic diagram of a first conductive layer in a display panel according to some embodiments of the present disclosure;

FIG. 16 is another layout schematic diagram of a pixel circuit in a display panel according to some embodiments of the present disclosure;

FIG. 17 is another schematic diagram of a first conductive layer in a display panel according some embodiments of the present disclosure;

FIG. 18 is another layout schematic diagram of a pixel circuit in a display panel according to some embodiments of the present disclosure;

FIG. 19 is another schematic diagram of a first conductive layer in a display panel according to some embodiments of the present disclosure; and

FIG. 20 is a schematic diagram of a display device according to some embodiments of the present disclosure.

Description of reference signs:
10, Pixel circuit; 11, Driving transistor; 12, First switching transistor; 121, First control portion; 122, Second control portion; 13, Second switching transistor; 14, First transistor;
20, Sub-pixel;
30, Substrate;
40, First conductive layer; 41, First conductor portion; 411, First sub-segment; 412, Second sub-segment; 413, Connecting segment; 414, Third sub-segment; 415, Fourth sub-segment; 42, Second conductor portion; 43, Third conductor portion; 44, Connecting portion;
50, Active layer; 51, First channel portion; 52, Second channel portion; 53, Third channel portion; 54, Fourth channel portion; 55, Fifth channel portion;
60, Second conductive layer; 61, First scanning line;
70, Third conductive layer;
H, First via;
X, First direction; Y, Second direction.

### DETAILED DESCRIPTION

Features and exemplary embodiments of various aspects of the present disclosure will be described in detail below. In order to make the objectives, technical solutions and advantages of the present disclosure clearer, the present disclosure will be further described in detail below with reference to the accompanying drawings and specific embodiments. It should be understood that the specific embodiments described here are only intended to explain the present disclosure, rather than limiting the present disclosure. It will be apparent to one skilled in the art that the present disclosure may implement the present disclosure without some of these specific details. The following description of the embodiments is only intended to provide a better understanding of the present disclosure by present some examples of the present disclosure.

It should be noted that in this description, relational terms such as first and second are only used to distinguish one entity or operation from another entity or operation, and do not necessarily require or imply that there is any such actual relationship or sequence between these entities or operations. Furthermore, the terms "comprise", "include", or any other variation thereof, are intended to cover a non-exclusive inclusion, such that a process, method, article, or apparatus that includes a list of elements does not include only those elements but also other elements not expressly listed or inherent to such process, method, article, or apparatus. Without more constraints, an element defined by the statement "comprise" does not preclude additional identical elements in the process, method, article, or device that includes the element.

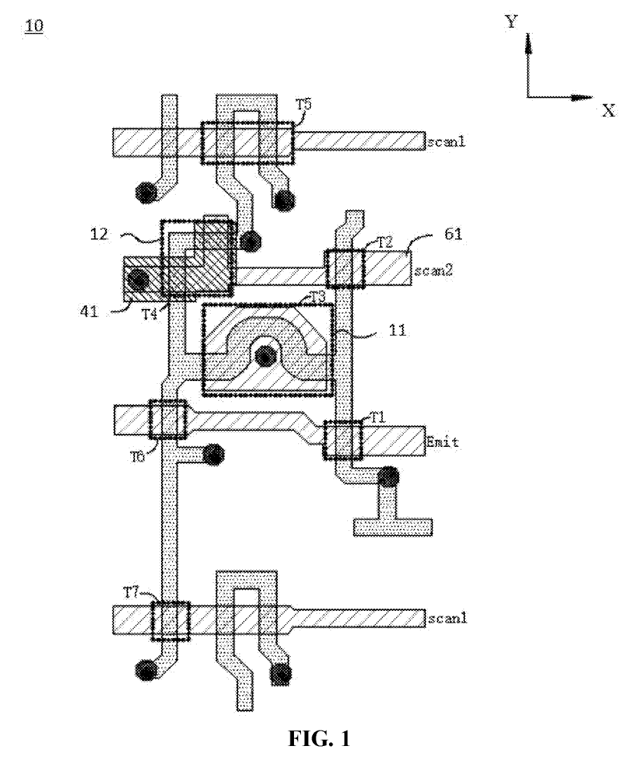

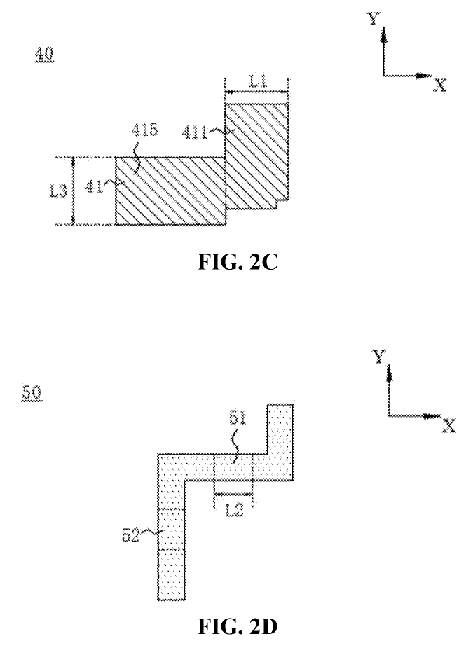

In a first aspect, referring to FIGS. 1 to 7, some embodiments of the present disclosure provide a display panel. The display panel includes a pixel circuit 10 and a sub-pixel 20. The pixel circuit 10 is configured to drive and control the sub-pixel 20. The pixel circuit 10 includes a driving transistor 11 and a first switching transistor 12. A control portion of the driving transistor 11 is electrically connected to a first electrode of the first switching transistor 12. Control portions of the first switching transistor 12 include a first control portion 121 and a second control portion 122. The display panel includes a substrate 30, a first conductive layer 40, an active layer 50, and a second conductive layer 60. The first conductive layer 40 is disposed on a side of the substrate 30 and includes a first conductor portion. The active layer 50 is disposed on a side of the first conductive layer 40 facing away from the substrate 30 and includes a first channel portion 51. An orthographic projection of the first channel portion 51 on the substrate 30 overlaps an orthographic projection of the first control portion 121 on the substrate 30. The first channel portion 51 is electrically connected to the first electrode of the first switching transistor 12. The second conductive layer 60 is disposed on a side of the active layer 50 facing away from the substrate 30, the first control portion 121 and the second control portion 122 are disposed in the second conductive layer 60. An orthographic projection of the first conductor portion on the substrate 30 overlaps the orthographic projection of the first channel portion 51 on the substrate 30, and the first conductor portion is configured to receive a variable voltage signal.

The display panel provided by the embodiments of the present disclosure can have various types. For example, the display panel can be an organic light-emitting display panel, or it can be a liquid crystal display panel. The sub-pixel 20 is the main structure for realizing the light-emitting function in the display panel. When the display panel is an organic light-emitting display panel, the sub-pixel 20 can include an organic light-emitting material, and an anode and a cathode that are located on both sides of the organic light-emitting material. When the display panel is a liquid crystal display panel, the sub-pixel 20 can include a liquid crystal structure, and a pixel electrode and a common electrode that are located on both sides of the liquid crystal structure.

The pixel circuit 10 is a circuit structure configured to control whether the sub-pixel 20 emits light in the display panel. The pixel circuit 10 can have various forms. For example, the pixel circuit 10 can have a 7T1C structure; that is, the pixel circuit 10 includes seven thin-film transistors and one storage capacitor. Alternatively, the pixel circuit 10 can also have a structure such as 8T1C, which is not limited in the embodiments of the present disclosure. Each thin-film transistor includes a control portion, a first electrode, and a second electrode, and the control portion is configured to control whether an electrical connection is established between the first electrode and the second electrode.

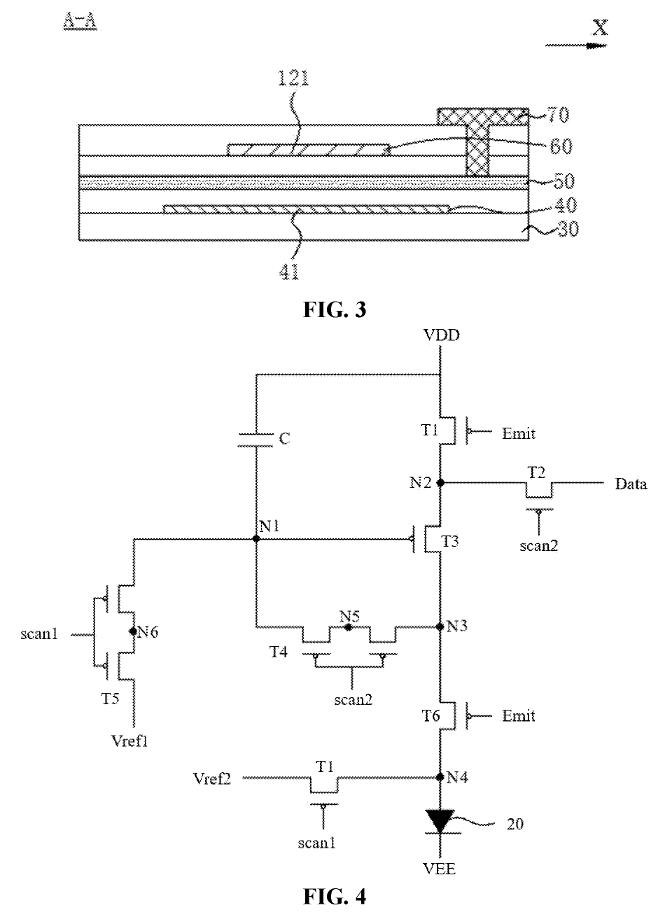

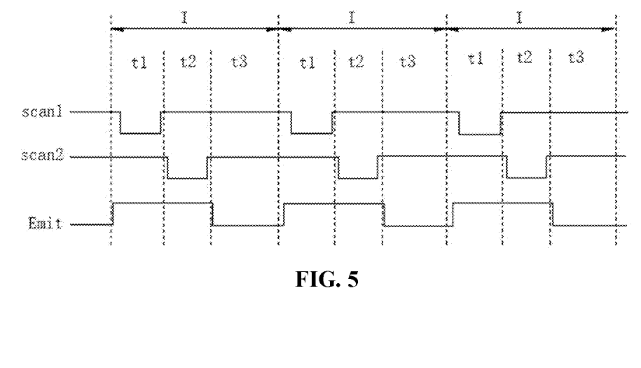

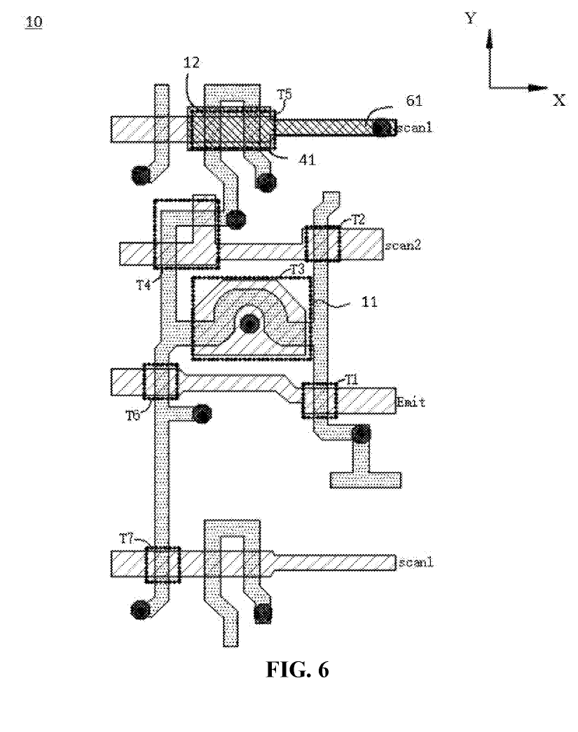

To facilitate understanding, some embodiments of the present disclosure will be described later by taking the pixel circuit 10 having a 7T1C structure and the display panel being an organic light-emitting display panel as an example. FIG. 4 is a simplified circuit diagram of a pixel circuit 10 that has a 7T1C structure, FIGS. 1 and 6 show layout structures of the pixel circuit 10 that has the 7T1C structure, and FIG. 5 shows a circuit timing sequence of the pixel circuit 10 that has the 7T1C structure.

The pixel circuit 10 includes a driving transistor 11, a first switching transistor 12, and five other switching transistors. The driving transistor 11 is a transistor T3. A control portion of the driving transistor 11 is electrically connected to a first node N1, and can be reused as one electrode plate structure of the storage capacitor C. A first electrode of the driving transistor 11 is configured to receive a first power supply signal VDD.

A control portion of the first switching transistor 12 is configured to receive a scanning signal, and a first electrode of the first switching transistor 12 is electrically connected to the control portion of the driving transistor. That is, the first electrode of the first switching transistor 12 is electrically connected to the first node N1. The first switching transistor 12 mentioned in the above embodiments of the present disclosure can be a transistor T4 or a transistor T5, which is not limited in the embodiments of the present disclosure. The scanning signals include a first scanning signal scan1 and a second scanning signal scan2. When the first switching transistor 12 is the transistor T4, the control portion of the first switching transistor 12 is configured to receive a second scanning signal scan2, and a second electrode of the first switching transistor 12 is electrically connected to a second electrode of the transistor T3. When the first switching transistor 12 is the transistor T5, the control portion of the first switching transistor 12 is configured to receive the first scanning signal scan1, and the second electrode of the first switching transistor 12 is configured to receive a first reset signal Vref1.

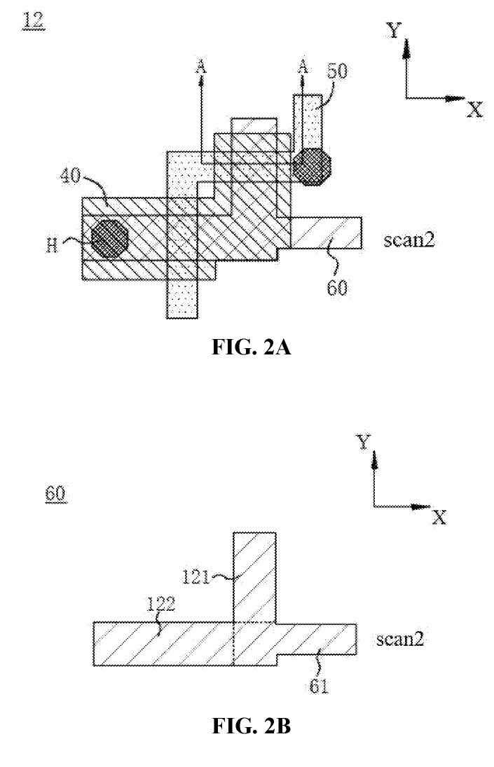

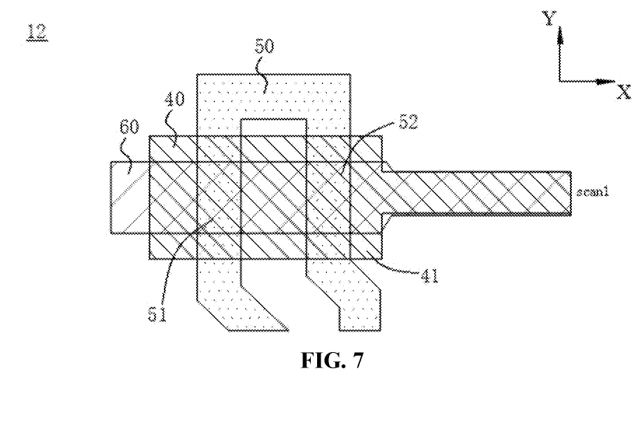

FIG. 1 shows a case where the first switching transistor 12 is the transistor T4, and FIGS. 2A to 2D are schematic diagrams of a local structure of the first switching transistor 12 in FIG. 1 and layer structures in the first switching transistor 12. FIG. 6 shows a case where the first switching transistor 12 is the transistor T5, and FIG. 7 is a partial schematic diagram of the first switching transistor 12 in FIG. 6.

Next, an operation process of the pixel circuit 10 will be briefly described in some embodiments of the present disclosure. As shown in FIGS. 4 and 5, within one frame time I, the pixel circuit 10 can include a reset phase, a charging phase, and a light-emitting phase. The reset phase corresponds to a t1 period. During the reset phase, the control portions of the switching transistor T5 and the transistor T7 are turned on by a low level of the first scanning signal scan1, and the first reset signal Vref1 is applied to the first node N1 to reset the control portion of the driving transistor 11 and one electrode plate structure of the storage capacitor C. A second reset signal Vref2 is applied to an anode of the sub-pixel 20 to reset the anode of the sub-pixel 20.

The charging phase corresponds to a t2 period during which the transistor T4 and the transistor T2 are turned on by a low level of the second scanning signal scan2. A data signal charges the first node N1 after being transmitted through the transistor T2, the transistor T3, and the transistor T4 (i.e., charging one electrode plate structure of the storage capacitor C), and a potential at the first node N1 increase. According to its own characteristics of the transistor T3, the potential at the first node N1 and a potential at a third node N3 during the charging process can be increased to Vdata+Vth, where Vdata represents a voltage value of the data signal Data and Vth represents a threshold voltage of the transistor T3. Since the transistor T3 being a PMOS transistor is taken as an example for illustration, the threshold voltage Vth here is a negative value.

The light-emitting phase is a t3 during which the transistor T1 and a transistor T6 are turned on by a low level of a light-emitting signal Emit, and a potential maintained at the first node N1 enables the transistor T3 to be turned on as well. The first power supply signal VDD is applied to the anode of the sub-pixel 20 after being transmitted through the transistor T1, the transistor T3, and the transistor T6, and a second power supply signal VEE is applied to a cathode of the sub-pixel 20. When driven by both the anode and the cathode of the sub-pixel 20, the organic light-emitting material in the sub-pixel 20 realizes the light-emitting function.

It should be noted that the structures shown in the drawings are all described by taking each thin-film transistor being a PMOS transistor (turned on under a low level and turned off under a high level) as an example. In the actual pixel circuit 10, some or all of the transistors can be adjusted to be NMOS transistors (turned on under a high level and turned off under a low level).

The control portion of the first switching transistor 12 includes a first control portion 121 and a second control portion 122; that is, the first switching transistor 12 has a dual-gate structure. Both the first control portion 121 and the second control portion 122 are located in the second conductive layer 60; that is, the first control portion 121 and the second control portion 122 include the same material and are manufactured and formed together in the same process. The first control portion 121 and the second control portion 122 are configured to receive a same signal. Specifically, when the first switching transistor 12 is the transistor T4, both the first control portion 121 and the second control portion 122 are configured to receive the second scanning signal scan2. When the first switching transistor 12 is the transistor T5, both the first control portion 121 and the second control portion 122 are configured to receive the first scanning signal scan1.

The active layer 50 is a layer structure including a semiconductor material in the display panel and includes a first channel portion 51, and an orthographic projection of the first channel portion 51 on the substrate 30 overlaps the orthographic projection of the first control portion 121. In addition to the first channel portion 51, the active layer 50 includes a second channel portion 52. An orthographic projection of the second channel portion 52 and an orthographic projection of the second control portion 122 on the substrate 30 overlap. Both the first channel portion 51 and the second channel portion 52 are channel structures of the first switching transistor 12. The first control portion 121 and the first channel portion 51 jointly form a first sub-transistor. The second control portion 122 and the second channel portion 52 jointly form a second sub-transistor. The first sub-transistor and the second sub-transistor are connected in series to form the first switching transistor 12.

It should be noted that the active layer 50 can have various material compositions, which are not limited in the embodiment of the present disclosure. For example, the first switching transistor 12 can be an indium gallium zinc oxide (IGZO)-TFT, and in this case, the material of the active layer 50 includes a metal oxide. Alternatively, the first switching transistor 12 can be a low temperature poly-silicon (LTPS)-TFT, and in this case, the material of the active layer 50 includes low-temperature polysilicon.

Compared with a single-gate transistor, the first switching transistor 12 is configured as a dual-gate transistor, facilitating improvement of the stability of the first switching transistor 12 when operating at a high-frequency. However, there is an intermediate node between the first sub-transistor and the second sub-transistor. When the first switching transistor 12 is the transistor T4, the intermediate node of the first switching transistor 12 is a fifth node N5. When the first switching transistor 12 is the transistor T5, the intermediate node of the first switching transistor 12 is a sixth node N6.

When the first switching transistor 12 is in the on state, the voltage at the intermediate node is usually kept the same as or similar to the voltage at the first node N1. When the first switching transistor 12 changes from the on state to the off state, the level of the control portion of the first switching transistor 12 will suddenly increase from a low level to a high level, which causes the voltage at the intermediate node to be easily coupled to a higher potential. In this way, there is a greater voltage difference between the intermediate node and the first node, which causes current leakage between the intermediate node and the first node; that is, the current leakage being likely to occur in the first channel portion 51. Under normal circumstances, the current leakage problem in the first channel portion 51 is usually continuous. During the light-emitting phase, the first channel portion 51 will continue to leak current, causing flicker of the display picture and degrading the actual usage experience.

In view of the above, in the embodiments of the present disclosure, the first conductive layer 40 is provided in the display panel. The first conductive layer 40 is located at an inner side of the active layer 50 away from the second conductive layer 60 and includes the first conductor portion 41. The orthographic projection of the first conductor portion 41 on the substrate 30 overlaps the orthographic projection of the first channel portion 51 on the substrate 30. On this basis, when the first switching transistor 12 is switched from the on state to the off state, an electrical conductivity of the first channel portion 51 can be changed by transmitting a specific signal voltage to the first conductor portion 41, thereby adjusting a degree of the current leakage between the intermediate node of the first switching transistor 12 and the first node N1 to improve the flicker problem of the display picture.

Furthermore, the first conductor portion 41 is configured to receive the variable voltage signal instead of a constant voltage signal; that is, signal voltages on the first conductor portion at different times are different. In this way, the first conductor portion 41 can affect the current leakage problem of the first channel portion 51 during the process in which the first switching transistor 12 changes from the on state to the off state by limiting and adjusting the timing sequence of the variable voltage signal. When the first switching transistor 12 is in the on state or the off state, the first conductor portion 41 has a small impact on the first channel portion 51, thereby improving the flicker problem of the display picture without affecting the normal operation of the first switching transistor 12.

In addition, since the first conductor portion 41 is located on the side of the first channel portion 51 facing towards the substrate 30, the first conductor portion 41 also helps to reduce the amount of reflected light propagating to the first channel portion 51, reduce the impact of reflected light inside the display panel on the performance of the first switching transistor 12, and improve operation reliability of the display panel.

It should be noted that the specific timing sequence and specific voltage value of the variable voltage signal are not limited in the embodiments of the present disclosure. In some optional embodiments, during the process in which the first switching transistor 12 changes from the on state to the off state, the signal voltage received by the first control portion 121 jumps to a high-level voltage, and the variable voltage signal received by the first conductor portion 41 is a low-level voltage. In this way, an electric field formed by the first control portion 121 and an electric field formed by the first conductor portion 41have opposite directions. Since the first control portion 121 and the first conductor portion 41 are disposed on two sides of the first channel portion 51, respectively, under a joint action of the two electric fields having opposite directions, induced charges can be formed faster on a surface of the first channel portion 51, and even forming an inversion layer, so that the threshold voltage of the first switching transistor 12 is forward-biased, and a movement rate of the leakage current in the first channel portion 51 is increased. In a short time, the potential at the first node N1 and the potential at the intermediate node in the first switching transistor 12 are kept consistent, thereby reducing the degree of the current leakage between the first node N1 and the intermediate node in the light-emitting phase, so that the potential at the first node N1 in the light-emitting phase can be more stable, thus improving the flicker problem of the display picture.

In some other optional embodiments, during the process in which the first switching transistor 12 changes from the on state to the off state, the signal voltage received by the first control portion 121 suddenly changes to a high-level voltage, and the variable voltage signal received by the first conductor portion 41 is a high-level voltage. In this way, the electric field formed by the first control portion 121 and the electric field formed by the first conductor portion 41 have a same direction. Since the first control portion 121 and the first conductor portion 41 are disposed on two sides of the first channel portion 51, respectively, under the joint action of the two electric fields having the same direction, a rate at which the induced charges are formed on the surface of the first channel portion 51 can be slowed down. In this way, the threshold voltage of the first switching transistor 12 is negatively biased and reduces the leakage current generated in the first channel portion 51. Therefore, in the light-emitting phase, only a small amount of leakage current or even no leakage current is formed in the first channel portion 51, which also helps to improve the flicker problem of the display picture.

A dimensional relationship between the first conductor portion 41 and the first channel portion 51 is not limited in the embodiments of the present disclosure. The orthographic projection of the first conductor portion 41 on the substrate 30 can be completely located within the orthographic projection of the first channel portion 51 on the substrate 30, or can be partially located outside the orthographic projection of the first channel portion 51 on the substrate 30. Furthermore, one first conductor portion 41 can correspondingly overlap the first channel portion 51 in only one pixel circuit 10, or can correspondingly overlap the first channel portions 51 in multiple pixel circuits 10. In addition, the first conductor portion 41 can correspondingly overlap only the channel structure of the first switching transistor 12 or can correspondingly overlap the channel structures of other transistors, which is not limited in the embodiments of the present disclosure.

In some embodiments, as shown in FIGS. 1, 2, 6, and 7, the active layer 50 includes a second channel portion 52 connected between the first channel portion 51 and the second electrode of the first switching transistor 12, and an orthographic projection of the second channel portion 52 on the substrate 30 overlaps the orthographic projection of the second control portion 122 on the substrate 30. The orthographic projection of the second channel portion 52 on the substrate 30 overlaps the orthographic projection of the first conductor portion 41 on the substrate 30.

The first channel portion 51 and the second channel portion 52 form a channel structure of the first switching transistor 12. The first channel portion 51 and the second channel portion 52 are spaced apart from each other. Exemplarily, the active layer 50 includes a mid-section, and the mid-section that is a part of the active layer 50 located between the first channel portion 51 and the second channel portion 52 and does not overlap the first control portion 121 and the second control portion 122. One of two ends of the mid-section are respectively connected to the first channel portion 51 and the second channel portion 52 to form one piece. Further optionally, the first conductor portion 41 correspondingly overlaps both the first channel portion 51 and the second channel portion 52, and at least part of the mid-section is located outside the orthographic projection of the first conductor portion 41 on the substrate 30.

In the embodiments of the present disclosure, the orthographic projection of the first conductor portion 41 on the substrate 30 overlaps both the orthographic projection of the first channel portion 51 on the substrate 30 and the orthographic projection of the second channel portion 52 on the substrate 30. In this way, during the process in which the first switching transistor 12 changes from the on state to the off state, the first conductor portion 41 can not only increase the current leaking rate of the first channel portion 51 or improve the current leakage problem in the first channel portion 51, but also increase the current leaking rate of the second channel portion 52 or improve the current leakage problem in the second channel portion 52, which help to further improve the potential stability at the first node N1 in the light-emitting phase, improve the flicker problem of the display picture, and improve the usage experience. In addition, such design also makes the orthographic projection of the first conductor portion 41 on the substrate 30 have a massive structure, thereby reducing the resistance and preparation difficulty of the first conductor portion 41, and also reducing the difficulty in aligning the first conductor portion 41 with the first switching transistors 12.

In some embodiments, as shown in FIGS. 1, 2, 6, and 7, the first conductor portion 41 is electrically connected to the first control portion 121.

As shown in FIGS. 1 and 2A, when the first switching transistor 12 is the transistor T4, the first control portion 121, the second control portion 122, and the first conductor portion 41 are all configured to receive the second scanning signal scan2. When the first switching transistor 12 is the transistor T5, the first control portion 121, the second control portion 122, and the first conductor portion 41 are all configured to receive the first scanning signal scan1.

The electrical connection manner between the first conductor portion 41 and the first control portion 121 is not limited in the embodiments of the present disclosure. Exemplarily, as shown in FIG. 2A, the first conductor portion 41 can be connected to the first control portion 121 through a first via H, and an orthographic projection of the first via H on the substrate 30 is located within the orthographic projection of the pixel circuit 10 on the substrate 30.

In the embodiments of the present disclosure, the first conductor portion 41 and the first control portion 121 have a same signal timing sequence by electrically connecting the first conductor portion 41 to the first control portion 121. Thus, in the process in which the first switching transistor 12 changes from the on state to the off state, both the first conductor portion 41 and the first control portion 121 become high-level voltages. In this way, under the joint action of the first conductor portion 41 and the first control portion 121, the leakage current generated in the first channel portion 51 can be reduced. Furthermore, in the light-emitting phase, there is only a small amount of leakage current or even no leakage current in the first channel portion 51, which also helps improve the flicker problem of the display picture.

In addition, since the first conductor portion 41 and the first control portion 121 are configured to receive a same signal, when the first switching transistor 12 is in the on state, both the first conductor portion 41 and the first control portion 121 are at a low level, so that the first control portion 121 will not hinder the conduction of the first switching transistor 12. Similarly, when the first switching transistor 12 is in the off state, the first conductor portion 41 and the first control portion 121 are both at a high level, so that the first control portion 121 will not cause the risk of the first switching transistor 12 being abnormally turned on, thereby improving the usage reliability of the first switching transistor 12.

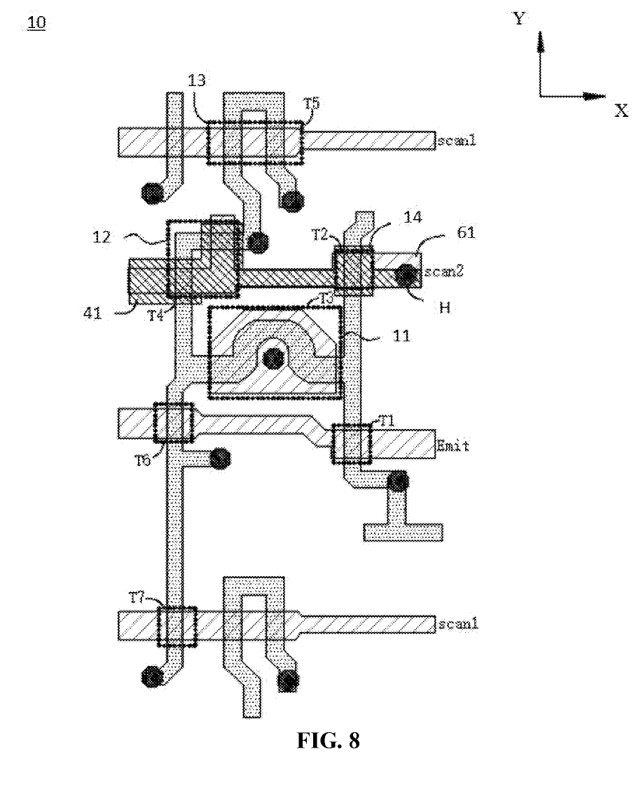

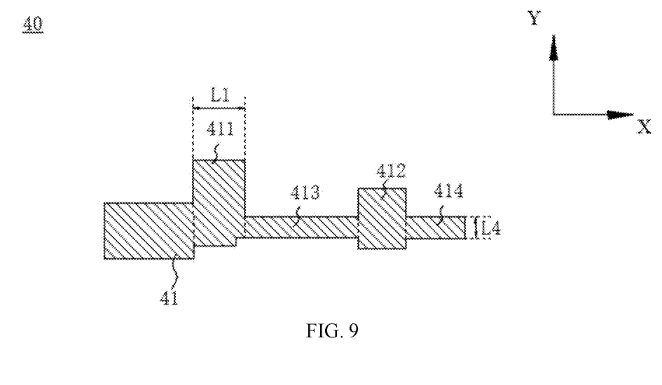

In some embodiments, referring to FIGS. 8 and 9 , the second conductive layer 60 includes a first scanning line 61 extending in a first direction X. The first scanning line 61 is electrically connected to the first control portion 121 and the second control portion 122, and the first direction X is parallel to the plane of the substrate 30. The first conductor portion 41 extends in the first direction X and is connected to the first scanning line 61.

The first scanning line 61 is a signal trace configured to transmit specific scanning signals to the first control portion 121 and the second control portion 122. When the first switching transistor 12 is the transistor T4, the first scanning line 61 is configured to transmit the second scanning signal scan2. When the first switching transistor 12 is the transistor T5, the first scanning line 61 is configured to transmit the first scanning signal scan1. The first scanning line 61 is electrically connected to the first control portion 121 and the second control portion 122. Exemplarily, with reference to FIGS. 2b and 2D a part of the first scanning line 61 overlapping the first channel portion 51 is also used as the first control portion 121, and a part of the first scanning line 61 overlapping the second channel portion 52 is reused as the second control portion 122.

It should be noted that "the first scanning line 61 extending in the first direction X" mentioned in the embodiments of the present disclosure refers to that a direction corresponding to the extending trend of the first scanning line 61 as a whole is the first direction X, which does not require that the first scanning line 61 is a straight line structure extending in the first direction X. This interpretation also holds true for t "first conductor portion 41 extending in the first direction X" mentioned in the embodiments of the present disclosure, which will not be repeated herein.

In some optional embodiments, taking the first switching transistor 12 being the transistor T4 and the first scanning line 61 being configured to transmit the second scanning signal scan2 as an example, the first scanning line 61 can include a main section and a protruding section that are formed into one piece. The main section is a straight line extending in the first direction X. The protruding section extends in the second direction Y and protrudes relative to the main section. The first direction X and the second direction Y are both parallel to the plane of the substrate 30 and intersect. On this basis, partial structure of the main section that correspondingly overlaps the first channel portion 51 is reused as the second control portion 122, and partial structure of the protruding section that correspondingly overlaps the second channel portion 52 is reused as the first control portion 121.

There are various connection manners between the first conductor portion 41 and the first scanning line 61. Exemplarily, when the orthographic projections of the first conductor portion 41 and the first scanning line 61 on the substrate 30correspondingly overlap, the first conductor portion 41 and the first scanning line 61 can be connected to each other through a via structure. Alternatively, the first conductor portion 41 and the first scanning line 61 can also be connected to each other through other transit traces, which is not limited in the embodiments of the present disclosure.

In the embodiments of the present disclosure, the first conductor portion 41 and the first scanning line 61 extend in a same direction, so that the first conductor portion 41 and the first scanning line 61 can have a same extending tendency. In this way, in regions of the display panel corresponding to different pixel circuits 10 in the first direction X, the orthographic projections of the first scanning line 61 and the first conductor portion 41 on the substrate 30 can have a same relative position relationship, thereby reducing the difficulty in connecting the first scanning line 61 with the first conductor portion 41 in different regions, and helping improve the reliability of the signal received by the first conductor portion 41.

In some embodiments, as shown in FIGS. 8 and 9, the orthographic projection of the first scanning line 61 on the substrate 30 overlaps the orthographic projection of the first conductor portion 41 on the substrate 30, and the first scanning line 61 and the first conductor portion 41 are connected to each other through the first via H.

In combination with the above contents, it can be known that the first scanning line 61 and the first conductor portion 41 can have the same extending direction. On this basis, in the embodiments of the present disclosure, the orthographic projection of the first scanning line 61 on the substrate 30 overlaps the orthographic projection of the first conductor portion 41 on the substrate 30, so that the first scanning line 61 and the first conductor portion 41 can be connected to each other through the first via H; thus it is unnecessary to add other transit traces in the display panel, and the wiring layout inside the display panel is simplified.

In addition, such design also helps to reduce the impact of the first conductor portion 41 on the transmittance of the display panel at a local position of the display panel and improve the display uniformity of the display panel. The specific positional relationship between the first conductor portion 41 and the first scanning line 61 is not limited in the embodiments of the present disclosure. The orthographic projection of the first conductor portion 41 on the substrate 30 can be completely located within the orthographic projection of the first scanning line 61 on the substrate 30, or the orthographic projection of the first conductor portion 41 on the substrate 30 can be partially located outside the orthographic projection of the first scanning line 61 on the substrate 30.

It should be noted that the first via H can have various layouts. Exemplarily, the orthographic projection of the first via H on the substrate 30 can be located in the pixel circuit 10. In this case, the orthographic projection of the first via H on the substrate 30 needs to avoid the active layer 50; that is, the orthographic projection of the first via H on the substrate 30 needs to be located outside the orthographic projection of the active layer 50 on the substrate 30, so as to reduce the risk of interference between the conductor material and the semiconductor material.

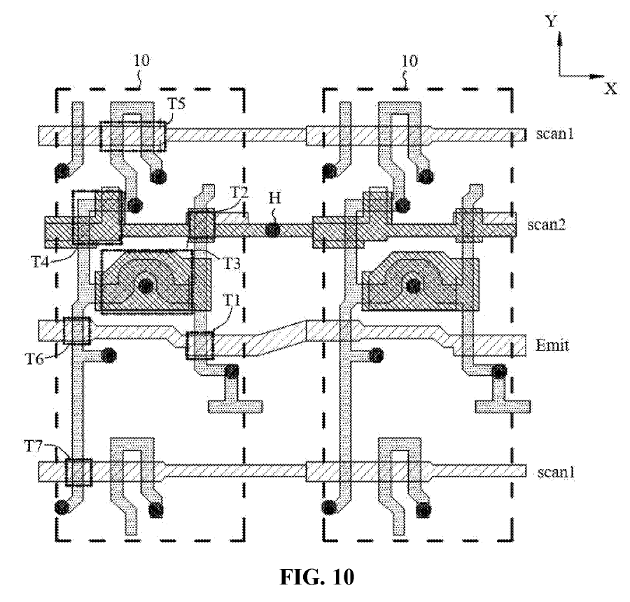

In some embodiments, referring to FIG. 10, multiple pixel circuits 10 are arranged in the first direction X, and the orthographic projection of the first via H on the substrate 30 is located between the orthographic projections, on the substrate 30, of two adjacent pixel circuits 10 along the first direction X.

The "two adjacent pixel circuits 10" mentioned in the embodiments of the present disclosure refers to that there is no other pixel circuit 10 between the two closest pixel circuits 10 in the first direction X; that is, between the two pixel circuits 10.

In a case where the first direction X is the row direction of the display panel, multiple pixel circuits 10 arranged in the first direction X jointly form a circuit row. Optionally, in addition to the multiple pixel circuits 10 being arranged in the first direction X, some pixel circuits 10 can be arranged in a second direction Y. Furthermore, the first direction X is perpendicular to the second direction Y. In this case, the pixel circuits 10 arranged in the second direction Y jointly form a circuit column.

In general, the active layer 50 is often not correspondingly located between two adjacent pixel circuits 10 along the first direction X. In view of this, in some embodiments of the present disclosure, the position of the first via H is adjusted in such a manner that the orthographic projection of the first via H on the substrate 30 is disposed between the orthographic projections of the two adjacent pixel circuits 10 on the substrate 30. In this way, the first via H will not interfere with the active layer 50, so that there is no need to adjust the structural size of the active layer, which helps to reduce the impact of the first via H on the performance of the active layer 50 and improve the usage reliability of the display panel.

In some embodiments, referring to FIGS. 8, 9, and 11, the pixel circuit 10 includes a first transistor 14, the active layer 50 includes a third channel portion 53, and an orthographic projection of the third channel portion 53 on the substrate 30 overlaps an orthographic projection of a control portion of the first transistor 14 on the substrate 30. The orthographic projection of the third channel portion 53 on the substrate 30 overlaps the orthographic projection of the first conductor portion 41 on the substrate 30.

The first transistor 14 is another transistor in the pixel circuit 10 that is different from the first switching transistor 12 and the driving transistor 11. The third channel portion 53 is a channel structure in the first transistor 14, and the first channel portion 51, the second channel portion 52, and the third channel portion 53 are provided in a same layer; that is, they include the same material and are manufactured and formed together in the same process. Optionally, the materials of the first channel portion 51, the second channel portion 52, and the third channel portion 53 each include low-temperature polysilicon; that is, the first switching transistor 12 and the first transistor 14 each are a LTPS-TFT.

The relative positional relationship between the first transistor 14 and the first switching transistor 12 is not limited in the embodiments of the present disclosure. Optionally, the first transistor 14 can be adjacent to the first switching transistor 12; that is, there is no other transistor between the two transistors. The first transistor 14 and the first switching transistor 12 can be arranged in the first direction X or in the second direction Y.

Optionally, the first transistor 14 and the first switching transistor 12 are two transistors adjacent to each other in the first direction X. Since the first conductor portion 41 can extend in the first direction X, the first conductor portion 41 can correspondingly overlap the first channel portion 51 and the third channel portion 53 by increasing the extending length of the first conductor portion 41.

In the embodiments of the present disclosure, by increasing the size of the first conductor portion 41, the first conductor portion 41 not only correspondingly overlaps the channel structure in the first switching transistor 12 but also correspondingly overlaps the third channel portion 53 in the first transistor 14. With such design, the first conductor portion 41 can also block light for the first transistor 14, which reduces the amount of reflected light propagating to the third channel portion 53, reduces the interference of the reflected light to the first transistor 14, and improves the operational reliability of the first transistor 14.

In some embodiments, as shown in FIGS. 8, 9, and 11, the second conductive layer 60 includes a first scanning line 61 extending in a first direction X. The first scanning line 61 is electrically connected to the first control portion 121 and the second control portion 122, and the first direction X is parallel to the plane of the substrate 30. The first conductor portion 41 includes a first sub-segment 411, a second sub-segment 412, and a connecting segment 413 that are connected into one piece. An orthographic projection of the first sub-segment 411 on the substrate 30 overlaps the orthographic projection of the first channel portion 51 on the substrate 30. An orthographic projection of the second sub-segment 412 on the substrate 30 overlaps the orthographic projection of the third channel portion 53 on the substrate 30. The connecting segment 413 extends in the first direction X, and two ends of the connecting segment 413 are respectively connected to the first sub-segment 411 and the second sub-segment 412. An orthographic projection of the connecting segment 413 on the substrate 30 overlaps the orthographic projection of the first scanning line 61 on the substrate 30.

The first sub-segment 411 is a partial structure of the first conductor portion 41 that correspondingly overlaps the first channel portion 51. The second sub-segment 412 is a partial structure of the first conductor portion 41 that correspondingly overlaps the third channel portion 53, and the connecting segment 413 is configured to be connected to both the first sub-segment 411 and the second sub-segment 412 to form one piece. A width of the first sub-segment 411 can be equal to a width of the connecting segment 413, or the width of the first sub-segment 411 can be less than or greater than the width of the connecting segment 413. The width relationship between the second sub-segment 412 and the connecting segment 413 is similar to the above width relationship between the first sub-segment 411 and the connecting segment 413.

In conjunction with the drawings, it can be seen that different transistors are usually disposed at intervals. To meet the overlapping requirement of the first conductor portion 41 relative to the channel structures of different transistors, the first conductor portion 41 needs to be provided with at least three segmented structures, i.e., the first sub-segment 411, the second sub-segment 412, and the connecting segment 413. On this basis, in some embodiments of the present disclosure, the relative positional relationship between the connecting segment 413 and the first scanning line 61 is further limited, so that the orthographic projection of the connecting segment 413 on the substrate 30 overlaps the orthographic projection of the first scanning line 61 on the substrate 30, thereby reducing the impact of the connecting segment 413 on the transmittance of the display panel in a local region of the display panel, and improving the display uniformity of the display panel.

In addition, since the orthographic projection of the connecting segment 413 on the substrate 30 is located outside the orthographic projection of the active layer 50 on the substrate 30 and overlaps the orthographic projection of the first scanning line 61 on the substrate 30, the first conductor portion 41 can be electrically connected to the first scanning line 61 through a via at a position corresponding to the connecting segment 413. In this way, the first conductor portion 41 and the first scanning line 61 can be connected in the region where a single pixel circuit 10 is located. In other cases, the first conductor portion 41 can correspondingly overlap the first scanning line 61 at other positions than the connecting segment 413, and the first conductor portion 41 is connected to the first scanning line 61 through a via at this position, which is not limited in the embodiments of the present disclosure.

In some optional embodiments, the first channel portion 51 and the third channel portion 53 are arranged in the first direction X, the connecting segment 413 and the first scanning line 61 both extend in the first direction X, and two ends of the connecting segment 413 in the first direction X are respectively connected to the first sub-segment 411 and the second sub-segment 412 to form one piece. In this case, the extending directions of the first conductor portion 41 and the first scanning line 61 are both the first direction X, thereby reducing the difficulty in connecting the first conductor portion 41 with the first scanning line 61.

In some embodiments, as shown in FIGS. 4 and 8, the second electrode of the first switching transistor 12 is electrically connected to a second electrode of the driving transistor 11, and a first electrode of the first transistor 14 is configured to receive the data signal. In other words, the first switching transistor 12 is the transistor T4, the first transistor 14 is the transistor T2, and the first scanning line 61 is configured to transmit the second scanning signal scan2.

In the embodiments of the present disclosure, the first conductor portion 41 correspondingly overlaps both the channel structure of the transistor T4 and the channel structure of the transistor T2. On the one hand, such design can reduce the degree of the current leakage between the fifth node N5 and the first node N1, thereby improving the flicker problem of the display picture. On the other hand, the first conductor portion 41 can also block light for the channel structures of the transistor T4 and the transistor T2, reducing the impact of the reflected light on the transistor T4 and the transistor T2, and improving the operation reliability of the transistor T4 and the transistor T2.

In addition, since the channel structure of the transistor T4 and the channel structure of the transistor T2 are spaced apart from each other in the first direction X, the first conductor portion 41 needs to extend along the first direction X to correspondingly overlap the channel structures of the transistors T2 and T4 each. In this case, the first conductor portion 41 and the first scanning line 61 have a same extending direction, thereby helping reduce the difficulty in connecting the first conductor portion 41 with the first scanning line 61.

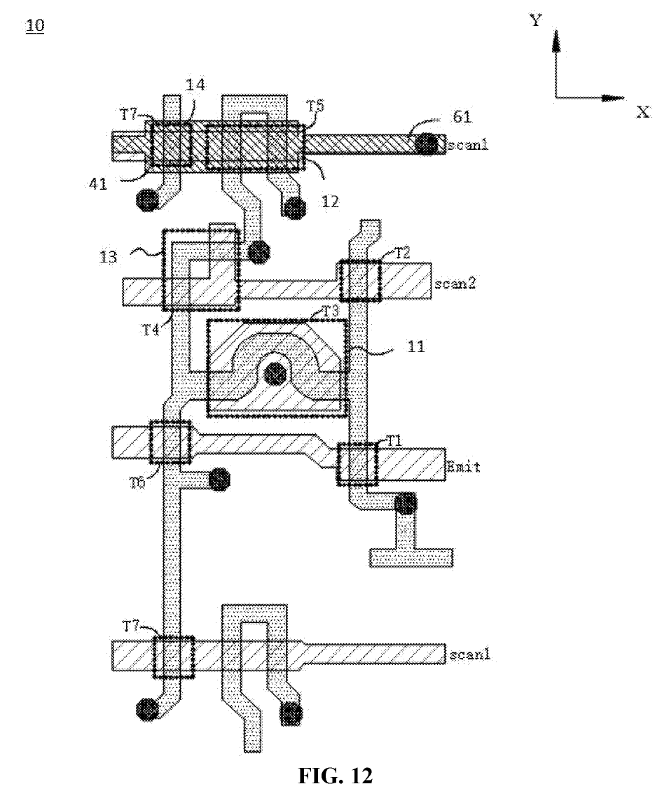

Alternatively, in some other embodiments, referring to FIGS. 4 and 12, the sub-pixel 20 includes an anode. The second electrode of the first switching transistor 12 is configured to receive the first reset signal Vref1, the first electrode of the first transistor 14 is configured to receive the second reset signal Vref2, and the second electrode of the first transistor 14 is electrically connected to the anode. In other words, the first switching transistor 12 is the transistor T5, the first transistor 14 is the transistor T7, and the first scanning line 61 is configured to transmit the first scanning signal scan1.

In the embodiments of the present disclosure, the first conductor portion 41 correspondingly overlaps both the channel structure of the transistor T5 and the channel structure of the transistor T7. On the one hand, such design can adjust the degree of the current leakage between the sixth node N6 and the first node N1, thereby improving the flicker problem of the display picture. On the other hand, the first conductor portion 41 can block light for the channel structures of the transistor T5 and the transistor T7, thereby reducing the impact of the reflected light on the transistor T5 and the transistor T7 and improving the operational reliability of the transistor T5 and the transistor T7.

In addition, since the channel structure of the transistor T5 and the channel structure of the transistor T7 are spaced apart from each other in the first direction X, the first conductor portion 41 needs to extend in the first direction X to correspondingly overlap the channel structures of the two transistors. In this case, the first conductor portion 41 and the first scanning line 61 have a same extending direction, thereby helping reduce the difficulty in connecting the first conductor portion 41 with the first scanning line 61.

In some embodiments, as shown in FIGS. 2A to 2D, the first conductor portion 41 includes a first sub-segment 411, and the orthographic projection of the first channel portion 51 on the substrate 30 is located within an orthographic projection of the first sub-segment 411 on the substrate 30.

The orthographic projection of the first channel portion 51 on the substrate 30 is located within the orthographic projection of the first sub-segment 411 on the substrate 30, which indicates that a dimension of the orthographic projection of the first sub-segment 411 is not smaller than a dimension of the orthographic projection of the first channel portion 51. Optionally, the orthographic projection of the first sub-segment 411 on the substrate 30 covers and exceeds the orthographic projection of the first channel portion 51 on the substrate 30. Furthermore, the first sub-segment 411 is beyond the first channel portion 51 in a width direction of the first sub-segment 411.

The "width direction" herein refers to a dimension of the first sub-segment 411 in a direction perpendicular to its extending direction. In different cases, the extending direction of the first sub-segment 411 can be the same as or different from the general extending direction of the first conductor portion 41, which results in that the first sub-segment 411 has different width directions in different cases. For example, as shown in FIGS. 2A to 2D, in a case where the first switching transistor 12 is the transistor T4, the first conductor portion 41 extends in the first direction X as a whole, but the first sub-segment 411 extends in the second direction Y, and the first conductor portion 41 and the first sub-segment 411 extend in different directions, respectively. In this case, the width direction of the first sub-segment 411 is the first direction X. In other words, when the first switching transistor 12 is the transistor T4, a size L1 of the first sub-segment 411 in the first direction X can exceed a size L2 of the first channel portion 51 in the first direction X.

In a case where the first switching transistor 12 is the transistor T5, the first conductor portion 41 generally extends in the first direction X, and the first sub-segment 411 extends in the first direction X, and the extending directions of the first conductor portion 41 and the first sub-segment 411 are the same. In this case, the width direction of the first sub-segment 411 is the second direction Y. In other words, when the first switching transistor 12 is the transistor T5, the first sub-segment 411 is beyond the first channel portion 51 in the second direction Y.

In the embodiments of the present disclosure, the orthographic projection of the first channel portion 51 on the substrate 30 is located within the orthographic projection of the first sub-segment 411 on the substrate 30 by increasing the size of the first sub-segment 411. In this way, the first sub-segment 411 can form an electrostatic shield around the first channel portion 51, reducing the interference of the external electrostatic field on the first switching transistor 12, and improving the operation reliability of the first switching transistor 12.

In some optional embodiments, the first conductor portion 41 includes a fourth sub-segment 415, and the orthographic projection of the second channel portion 52 on the substrate 30 is located within an orthographic projection of the fourth sub-segment on the substrate 30. Furthermore, the fourth sub-segment 415 in its width direction extends beyond the first channel portion 51, a size L3 of the fourth sub-segment 415 in its width direction is greater than a size of the first channel portion 51 in the width direction of the fourth sub-segment 415. When the first switching transistor 12 is the transistor T4, the width direction of the first sub-segment 411 is the first direction X, and the width direction of the fourth sub-segment 415 is the second direction Y. When the first switching transistor 12 is the transistor T5, the width directions of the first sub-segment 411 and the fourth sub-segment 415 are both the second direction Y.

In some embodiments, referring to FIGS. 8 and 9, the first conductor portion 41 includes a third sub-segment 414, and an orthographic projection of the third sub-segment 414 on the substrate 30 is located outside the orthographic projection of the active layer 50 on the substrate 30. A width L1 of the first sub-segment 411 is greater than a width L4 of the third sub-segment 414.

The third sub-segment 414 is a partial structure in the first conductor portion 41 that does not overlap the active layer 50. The connecting segment 413 is a partial structure in the third sub-segment 414. As can be seen from the above contents, for the first sub-segment 411, the width L1 of the first sub-segment 411 can be increased so that the first sub-segment 411 extends beyond the first channel portion 51 in the width direction of the first sub-segment 411, thereby reducing the interference of the external electrostatic field on the first switching transistor 12. However, for the third sub-segment 414, in a case where the width L4 of the third sub-segment 414 is too large, it is easy to generate signal interference to other trace structures, and it is easy to affect the layout of other traces inside the display panel and the transmittance of the display panel in a local region.

In view of this, in the embodiments of the present disclosure, the sizes of the first sub-segment 411 and the third sub-segment 414 are designed to be different, and the width L1 of the first sub-segment 411 is set to be greater than the width L4 of the third sub-segment 414. In this way, on the one hand, an antistatic ability of the first switching transistor 12 is improved by means of the first sub-segment 411, and on the other hand, the impact of the signal interference between the third sub-segment 414 and other signal traces is reduced, and the impact of the third sub-segment 414 on wiring layouts of other traces and the transmittance of the display panel in its local region is reduced, which has strong practicability.

In some embodiments, as shown in FIG. 10, the orthographic projection of one first conductor portion 41 on the substrate 30 overlaps the orthographic projections of the corresponding first channel portions 51 in multiple pixel circuits 10 on the substrate 30.

In the embodiments of the present disclosure, one first conductor portion 41 does correspondingly overlap not only first channel portion 51 in one pixel circuit 10, but correspondingly overlaps multiple first channel portions 51 in multiple pixel circuits 10. In this way, with one first conductor portion 41, the current leakage problem of the multiple pixel circuits 10 can be improved. Such design helps to reduce the number of the first conductor portions 41 in the display panel and the number of the vias required to realize the connection between the first conductor portion 41 and the first scanning line 61, thereby simplifying the manufacturing difficulty of the first conductive layer 40. Optionally, the first conductor portion 41 extends in the first direction X, and one first conductor portion 41 correspondingly overlaps the first channel portions 51 in the multiple pixel circuits 10 arranged in the first direction X.

In some embodiments, as shown in FIGS. 4 and 8, the pixel circuit 10 includes a second switching transistor 13. A first electrode of the second switching transistor 13 is electrically connected to the control portion of the driving transistor 11, and control portions of the second switching transistor 13 include a third control portion and a fourth control portion. The second electrode of the first switching transistor 12 is electrically connected to the second electrode of the driving transistor 11, and a second electrode of the second switching transistor 13 is configured to receive the first reset signal Vref1.

The second switching transistor 13 has a dual-gate structure, and the third control portion and the fourth control portion in the second switching transistor 13 are both located in the second conductive layer 60; that is, the third control portion and the fourth control portion include the same material and are both manufactured and formed together in the same process. The third control portion and the fourth control portion are configured to receive a same signal. Specifically, both the first control portion 121 and the second control portion 122 are configured to receive the second scanning signal scan2, and both the third control portion and the fourth control portion are configured to receive the first scanning signal scan1.

In the embodiments of the present disclosure, the first switching transistor 12 is the transistor T4, the second switching transistor 13 is the transistor T5, and the first conductor portion 41 can correspondingly overlap the channel structure in the transistor T4 to reduce the degree of the current leakage between the fifth node N5 and the first node N1, thereby improving the flicker problem of the display picture.

In other embodiments, as shown in FIGS. 4 and 12, the second electrode of the second switching transistor 13 is electrically connected to the second electrode of the driving transistor 11, and the second electrode of the first switching transistor 12 is configured to receive the first reset signal Vref1.

In the embodiment of the present disclosure, the first switching transistor 12 is the transistor T5, the second switching transistor 13 is the transistor T4, the first control portion 121 and the second control portion 122 are both configured to receive the first scanning signal scan1, and the third control portion and the fourth control portion are both configured to receive the second scanning signal scan2. The first conductor portion 41 can correspondingly overlap the channel structure in the transistor T5, so as to reduce the degree of the current leakage between the sixth node N6 and the first node N1, thereby improving the flicker problem of the display picture.

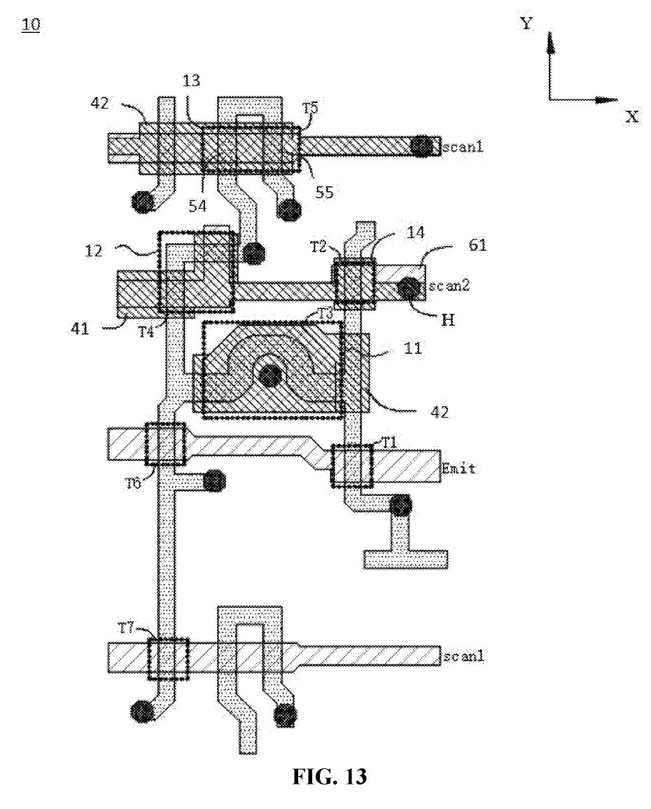

In some embodiments, referring to FIG. 13, the active layer 50 includes a fourth channel portion 54. An orthographic projection of the fourth channel portion 54 on the substrate 30 overlaps the orthographic projection of the third control portion on the substrate 30. The fourth channel portion 54 is electrically connected to the first electrode of the second switching transistor 13. The first conductive layer 40 includes a second conductor portion 42, and an orthographic projection of the second conductor portion 42 on the substrate 30 overlaps the orthographic projection of the fourth channel portion 54 on the substrate 30. The second conductor portion 42 is electrically connected to the third control portion and is insulated from the first conductor portion 41.

The orthographic projections of the fourth channel portion 54 and the third control portion on the substrate 30 overlap. In addition to the fourth channel portion 54, the active layer 50 includes a fifth channel portion 55. The orthographic projections of the fifth channel portion 55 and the fourth control portion on the substrate 30 overlap. Both the fourth channel portion and the fifth channel portion 55 are channel structures of the second switching transistor 13. The third control portion and the fourth channel portion 54 jointly form a third sub-transistor, the fourth control portion and the fifth channel portion 55 jointly form a fourth sub-transistor, and the third sub-transistor and the fourth sub-transistor are connected in series to form the second switching transistor 13.

For the first switching transistor 12 and the second switching transistor 13 that are electrically connected to the control portion of the driving transistor 11, during the process where each of the first switching transistor 12 and the second switching transistor 13 changes from the on state to the off state, it is easy to cause a voltage difference between the intermediate node and the first node N1, thereby causing current leakage problem.

In view of this, in the embodiments of the present disclosure, the first conductive layer 40 is provided with both the first conductor portion 41 and the second conductor portion 42, the first conductor portion 41 is insulated from the second conductor portion 42, is electrically connected to the first control portion 121 and correspondingly overlaps the first channel portion 51, and the second conductor portion 42 is electrically connected to the third control portion and correspondingly overlaps the fourth channel portion 54. In this way, with the first conductor portion 41 and the second conductor portion 42, not only the degree of the current leakage between the fifth node N5 and the first node N1 but also the degree of the current leakage between the sixth node N6 and the first node N1 are reduced, thereby further improving the flicker problem of the display picture and improving the usage experience of the display panel.

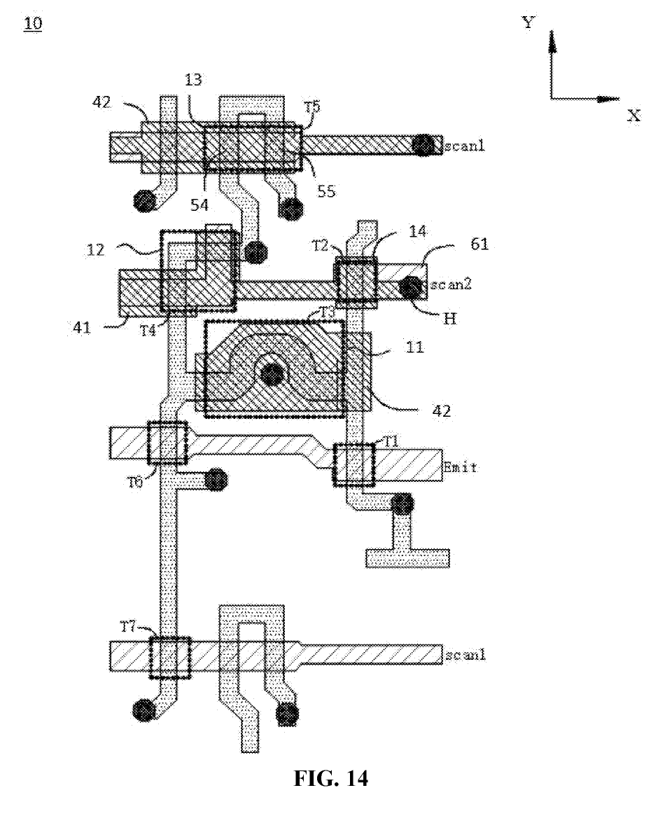

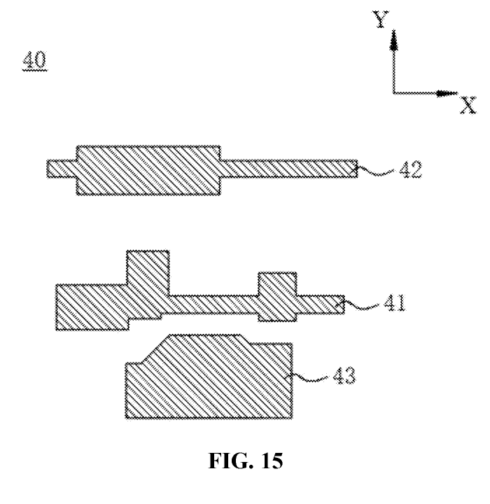

In some embodiments, referring to FIGS. 14 and 15, the first conductive layer 40 includes a third conductor portion 43. An orthographic projection of the third conductor portion 43 on the substrate 30 overlaps an orthographic projection of the control portion of the driving transistor 11 on the substrate 30, and the third conductor portion 43 is electrically connected to the control portion of the driving transistor 11.

The third conductor portion 43 and the first conductor portion 41 are both located in the first conductive layer 40; that is, the first conductor portion 41 and the third conductor portion 43 include the same material and are manufactured and formed together in the same process. The orthographic projection of the third conductor portion 43 on the substrate 30 overlaps the orthographic projection of the control portion of the driving transistor 11 on the substrate 30. Since the channel structure in the driving transistor 11 usually corresponds to the position of the control portion of the driving transistor 11, therefore, the third conductor portion 43 will correspondingly overlap the channel structure of the driving transistor 11.

In conjunction with the accompanying drawings, it can be seen that since the first switching transistor 12 and the driving transistor 11 are spaced apart from each other in the second direction Y, the first conductor portion 41 and the third conductor portion 43 corresponding to the two transistors will also be spaced apart from each other in the second direction Y, so that the first conductor portion 41 and the third conductor portion 43 are insulated from each other. On this basis, in the embodiments of the present disclosure, the third conductor portion 43 is electrically connected to the control portion of the driving transistor 11, so that the third conductor portion 43 can receive a specific signal voltage. In this way, the third conductor portion 43 can not only block light for the driving transistor 11 to improve the performance of the driving transistor 11, but also can improve the antistatic capability of the driving transistor 11 to improve the operational reliability of the pixel circuit 10.

The electrical connection method between the third conductor portion 43 and the driving transistor 11 is not limited in the embodiments of the present disclosure. Optionally, the display panel includes a storage capacitor, one electrode plate of the storage capacitor is reused as the control portion of the driving transistor 11, and an orthographic projection of this electrode plate on the substrate 30 can be partially located outside the orthographic projection of the active layer 50 on the substrate 30 and overlaps the orthographic projection of the third conductor portion 43 on the substrate 30. On this basis, the third conductor portion 43 can be directly connected to the electrode plate of the storage capacitor through a via, thereby realizing the electrical connection between the third conductor portion 43 and the driving transistor 11.

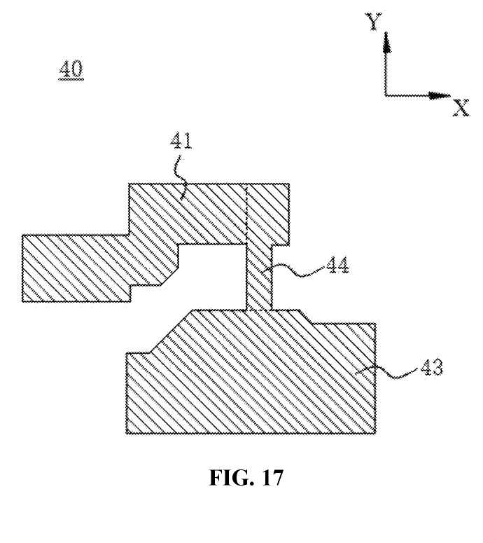

In some embodiments, referring to FIGS. 4, 16 and 17, the first conductor portion 41 is electrically connected to the control portion of the driving transistor 11.

In the embodiments of the present disclosure, by electrically connecting the first conductor portion 41 to the control portion of the driving transistor 11, the first conductor portion 41 can receive the signal voltage at the first node N1, so that the signal received by the first control portion 121 becomes a high-level voltage, and the signal received by the first conductor portion 41 is a low-level voltage during the first switching transistor 12 changes from the on state to the off state. In this way, under the joint action of the first conductor portion 41 and the first control portion 121, the current leakage rate of the first channel portion 51 can be increased, thereby completing the current leakage process in a relatively short time. Furthermore, when the display panel is in the light-emitting phase, the intermediate node of the first switching transistor 12 and the first node N1 can maintain voltage balance, and such design can improve the potential stability at the first node in the light-emitting phase and improve the flicker problem of the display picture.

In some embodiments, the first conductive layer 40 includes a third conductor portion 43, an orthographic projection of the third conductor portion 43 on the substrate 30 overlaps the orthographic projection of the control portion of the driving transistor 11 on the substrate 30, and the third conductor portion 43 is electrically connected to the control portion of the driving transistor 11.

The first conductor portion 41 and the third conductor portion 43 are both located in the first conductive layer 40; that is, the first conductor portion 41 and the third conductor portion 43 include the same material and are manufactured and formed together in the same process. Since the first conductor portion 41 and the third conductor portion 43 are both electrically connected to the control portion of the driving transistor 11, the first conductor portion 41 and the third conductor portion 43 can be connected to the same trace structure to realize the electrical connection between the first conductor portion 41 and the third conductor portion 43. Alternatively, the first conductor portion 41 and the third conductor portion 43 can also be spaced apart from each other, and are electrically connected to the control portion of the driving transistor 11 respectively through different trace structures.

In the embodiments of the present disclosure, since the third conductor portion 43 is electrically connected to the control portion of the driving transistor 11, and the third conductor portion 43 will correspondingly overlap the channel structure of the driving transistor 11, the third conductor portion 43 can not only block light for the driving transistor 11 to improve the performance of the driving transistor 11, but also improve the antistatic capability of the driving transistor 11 and improve the operational reliability of the pixel circuit 10.

In some embodiments, as shown in FIGS. 4, 16, and 17, the first conductive layer 40 includes a connecting portion 44, and the first conductor portion 41, the third conductor portion 43, and the first electrode of the first switching transistor 12 are all electrically connected to the connecting portion 44.

In conjunction with the accompanying drawings, it can be seen that the orthographic projection of the first conductor portion 41 on the substrate 30 and the orthographic projection of the control portion of the driving transistor 11 on the substrate 30 are distributed in a staggered manner, so the first conductor portion 41 cannot be directly connected to the control portion of the driving transistor 11 through a via. For the third conductor portion 43, the third conductor portion 43 and the control portion of the driving transistor 11 correspondingly overlap, so the third conductor portion 43 can be directly connected to the control portion of the driving transistor 11 through a via.

In view of the above, in the embodiments of the present disclosure, the connecting portion 44 is provided in the first conductive layer 40 and is connected between the first conductor portion 41 and the third conductor portion 43. In this way, the first conductor portion 41 can be electrically connected to the control portion of the driving transistor 11 by means of the connecting portion 44 and the third conductor portion 43, and there is no need to provide connection traces in other conductive layers other than the first conductive layer 40, thereby reducing the occupation of space in other layers and reducing the difficulty of wiring layout inside the display panel.

It should be noted that, in the related art, in order to enable the first electrode of the transistor T4 and the first electrode of the transistor T5 to be electrically connected to the control portion of the driving transistor 11, the display panel is provided with a third conductive layer on a side of the second conductive layer 60 facing away from the substrate 30. The third conductive layer includes a switching portion extending in the second direction Y, the scanning line for transmitting the second scanning signal scan2 extends in the first direction X, and the switching portion and the scanning line correspondingly overlaps manner. On this basis, two ends of the switching portion are located at two sides of the scanning line respectively, and one end of the switching portion is connected to one electrode plate structure of the storage capacitor through a via to achieve connection with the control portion of the driving transistor 11, and the other end of the switching portion is connected to the active layer 50 through a via to achieve connection with the first electrode of the transistor T4 and the first electrode of the transistor T5.

However, in the embodiments of the present disclosure, the connecting portion 44 provided in the first conductive layer 40 can be electrically connected to the control portion of the driving transistor 11. It can be seen in conjunction with the drawings that the connecting portion 44 can overlap the partial structures in the transistor T4 and the transistor T5 in the active layer 50. On this basis, in some optional embodiments, the connecting portion 44 and the active layer 50 can be connected through a via, so that the first electrode of the transistor T4 and the first electrode of the transistor T5 can be electrically connected to the control portion of the driving transistor 11, thereby omitting the switching portion in the third conductive layer and simplifying the internal wiring layout of the display panel.

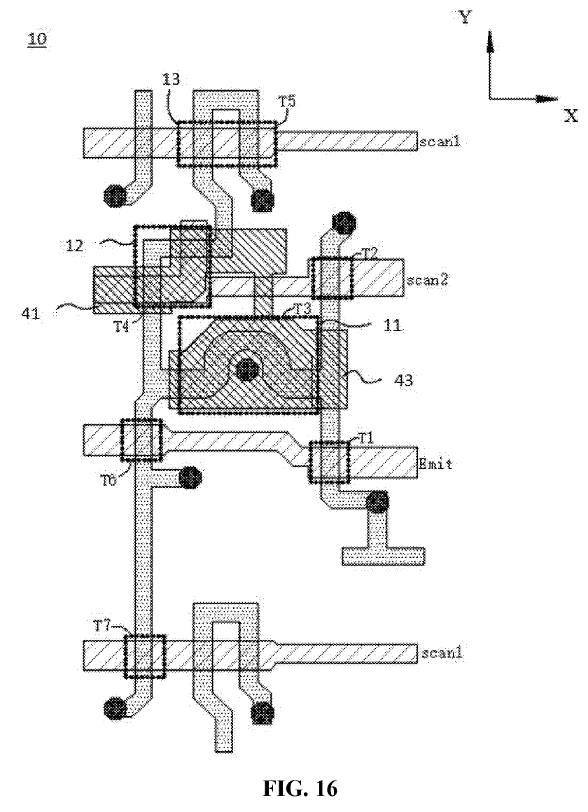

In some embodiments, as shown in FIG. 16, the pixel circuit 10 includes a second switching transistor 13. A first electrode of the second switching transistor 13 is electrically connected to the control portion of the driving transistor 11, and control portions of the second switching transistor 13 includes a third control portion and a fourth control portion. The second electrode of the first switching transistor 12 is electrically connected to the first electrode of the driving transistor 11, and a second electrode of the second switching transistor 13 receives the first reset signal Vref1.

The second switching transistor 13 has a dual-gate structure, and the third control portion and the fourth control portion in the second switching transistor 13 are both located in the second conductive layer 60; that is, the third control portion and the fourth control portion include the same material and are manufactured and formed together in the same process. The third control portion and the fourth control portion are configured to receive the same signal. Specifically, both the first control portion 121 and the second control portion 122 is configured to receive the second scanning signal scan2, and both the third control portion and the fourth control portion are configured to receive the first scanning signal scan1.

In the embodiments of the present disclosure, the first switching transistor 12 is the transistor T4, the second switching transistor 13 is the transistor T5, and the first conductor portion 41 can correspondingly overlap the channel structure in the transistor T4 to increase the current leakage rate between the fifth node N5 and the first node N1, thereby completing the current leakage process in a short time. Furthermore, when the display panel is in the light-emitting phase, the voltage balance between the fifth node N5 and the first node N1 can be maintained to improve the flicker problem of the display picture.

Alternatively, in some other embodiments, the second electrode of the second switching transistor 13 is electrically connected to the second electrode of the driving transistor 11, and the second electrode of the first switching transistor 12 is configured to receive the first reset signal Vref1.

In the embodiments of the present disclosure, the first switching transistor 12 is the transistor T5, the second switching transistor 13 is the transistor T4, the first control portion 121 and the second control portion 122 are both configured to receive the first scanning signal scan1, and the third control portion and the fourth control portion are both configured to receive the second scanning signal scan2. The first conductor portion 41 can correspondingly overlap the channel structure of the transistor T5 to increase the current leakage rate between the sixth node N6 and the first node N1, thereby completing the current leakage process in a short time. Furthermore, when the display panel is in the light-emitting phase, the sixth node N6 and the first node N1 can maintain the voltage balance to improve the flicker problem of the display picture.

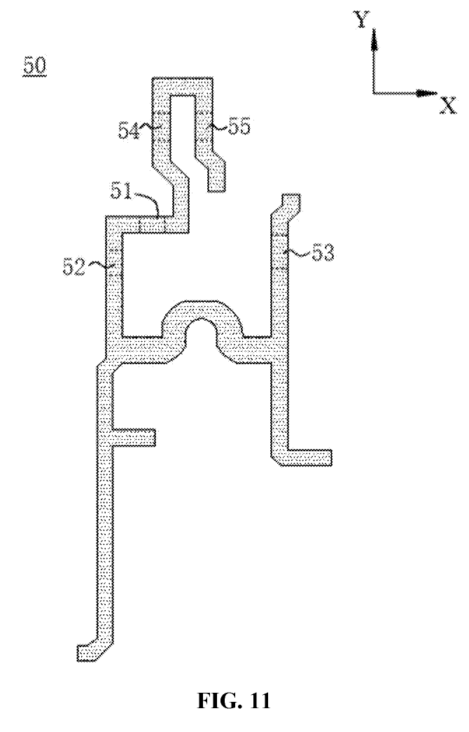

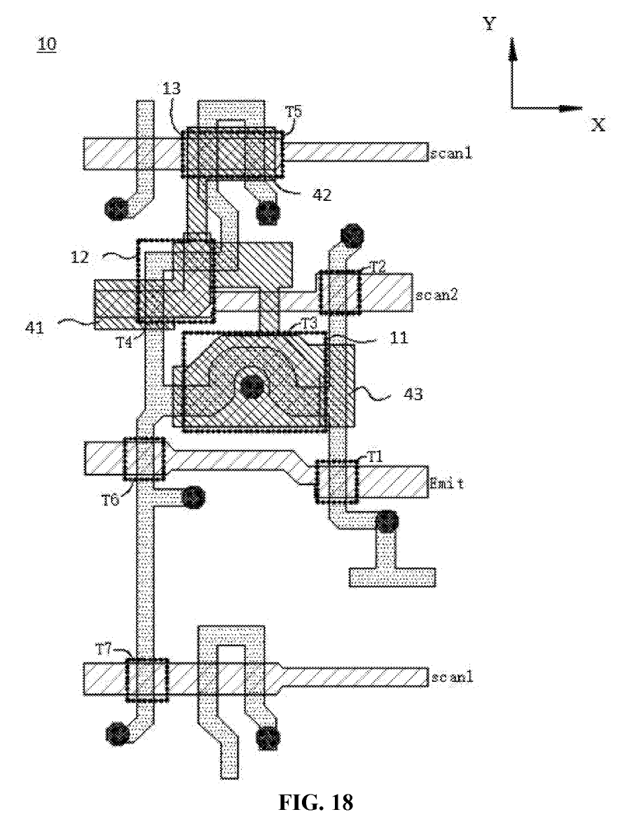

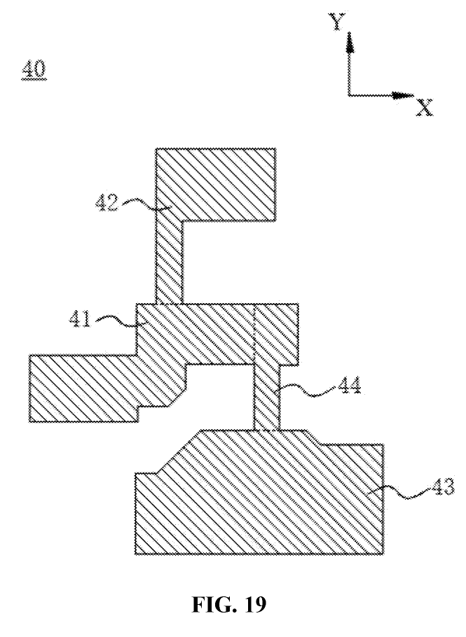

In some embodiments, referring to FIGS. 11, 18, and 19, the active layer 50 includes a fourth channel portion 54. An orthographic projection of the fourth channel portion 54 on the substrate 30 overlaps an orthographic projection of the third control portion on the substrate 30. The fourth channel portion 54 is electrically connected to the first electrode of the second switching transistor 13. The first conductive layer 40 includes a second conductor portion 42. An orthographic projection of the second conductor portion 42 on the substrate 30 overlaps an orthographic projection of the fourth channel portion 54 on the substrate 30. The first conductor portion 41 and the second conductor portion 42 are an integrated structure.

The orthographic projections of the fourth channel portion 54 and the third control portion on the substrate 30 overlap. In addition to the fourth channel portion 54, the active layer 50 includes a fifth channel portion 55. The orthographic projections of the fifth channel portion 55 and the fourth control portion on the substrate 30 overlap. Both the fourth channel portion 54 and the fifth channel portion 55 are channel structures of the second switching transistor 13. The third control portion and the fourth channel portion 54 jointly form a third sub-transistor, the fourth control portion and the fifth channel portion 55 jointly form a fourth sub-transistor, and the third sub-transistor and the fourth sub-transistor are connected in series to form the second switching transistor 13.

For the first switching transistor 12 and the second switching transistor 13 electrically connected to the control portion of the driving transistor 11, during the process of the two transistors changing from the on state to the off state, it is easy to cause a voltage difference between the intermediate node and the first node N1, thereby causing the current leakage problem.

In view of the above, in the embodiments of the present disclosure, both the first conductor portion 41 and the second conductor portion 42 are provided in the first conductive layer 40, and both the first conductor portion 41 and the second conductor portion 42 are electrically connected to the control portion of the driving transistor 11. In this way, the current leakage rate between the fifth node N5 and the first node N1 can be accelerated, and the current leakage rate between the sixth node N6 and the first node N1 can also be increase by means of the first conductor portion 41 and the second conductor portion 42. Therefore, when the display panel is in the light-emitting phase, the first node N1 can maintain voltage balance with the fifth node N5 and can also maintain voltage balance with the sixth node N6, thereby improving the flicker problem of the display picture.

Further, since the first conductor portion 41 and the second conductor portion 42 are both electrically connected to the control portion of the driving transistor 11, and the first switching transistor 12 is relatively close to the second switching transistor 13, the first conductor portion 41 and the second conductor portion 42 are also connected into one piece in the embodiments of the present disclosure, so as to satisfy the signal transmission requirement. At the same time, it is also helpful to simplify the difficulty of wiring layout of the display panel, which has strong practicability.

It should be noted that, for different pixel circuits 10, at the same moment, the signal voltages of different pixel circuits 10 at the first node N1 are different. In view of this, the different first conductor portions 41 corresponding to different pixel circuits 10 need to be spaced apart from each other, so as to meet the normal operation requirements of the pixel circuits 10.

In some embodiments, multiple sub-pixels 20 include a first sub-pixel 20 configured to emit green light, and multiple pixel circuits 10 include a first pixel circuit 10 configured to drive the first sub-pixel 20. The orthographic projection of the first conductor portion 41 on the substrate 30 overlaps the orthographic projection of the first channel portion 51 in the first pixel circuit 10 on the substrate 30.

The first sub-pixel 20 is the sub-pixel 20 configured to emit green light in the multiple sub-pixels 20, and the first pixel circuit 10 is the pixel circuit 10 configured to drive the first sub-pixel 20 in the multiple pixel circuits 10. Optionally, in addition to the first sub-pixel 20, the multiple sub-pixels 20 can also include a second sub-pixel 20 configured to emit red light and a third sub-pixel 20 configured to emit blue light.

Human eyes are sensitive to green. Therefore, compared with sub-pixels 20 of other colors, the first sub-pixel 20 for emitting green light has a greater impact on the display effect. In view of this, in the embodiments of the present disclosure, the first conductor portion 41 is provided at a position corresponding to the first channel portion 51 in the first pixel circuit 10, and the degree of current leakage in the first pixel circuit 10 is adjusted by means of the first conductor portion 41, thereby improving the flicker problem corresponding to the first sub-pixel 20.

It should be noted that the embodiments of the present disclosure does not limit the relationship between the pixel circuit 10 corresponding to other sub-pixels and the first conductor portion 41. Exemplarily, the display panel can be provided with the first conductor portion 41 only at the position corresponding to the first channel portion 51 in the first pixel circuit 10, or it can also be provided with the first conductor portion 41 at the position corresponding to the first channel portions 51 in the pixel circuits 10 of other sub-pixels 20.

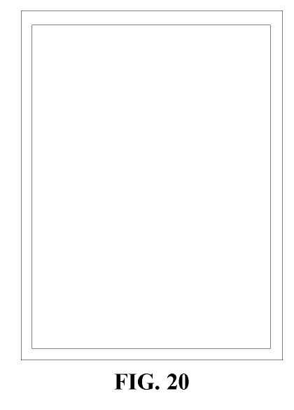

In a second aspect, referring to FIG. 20, some embodiments of the present disclosure provide a display device, and the display device includes the display panel provided in any one of the foregoing embodiments.

It should be noted that the display device provided by the embodiments of the present disclosure has the beneficial effects of the display panel provided in any of the foregoing embodiments. Details can refer to the foregoing description of the beneficial effects of the display panel, which is not limited by the embodiments of the present disclosure. Furthermore, in addition to the display panel, the display device can include a mid-frame, which is at least partially disposed at a peripheral of the display panel to protect the display panel.

Although the embodiments disclosed in the present disclosure are as above, the contents described are only embodiments adopted to facilitate understanding of the present disclosure, and are not intended to limit the present disclosure. Any person skilled in the art to which the present disclosure belongs can make any modifications and changes in the form and details of implementation without departing from the spirit and scope of the present disclosure. However, the protection scope of the present disclosure should still defined by the appended claims.

The foregoing descriptions are merely specific implementations of the present disclosure. It can be clearly understood by those skilled in the art that, for the purpose of convenient and brief description, for the replacement of other connection manners described above, reference can be made to the corresponding processes in the foregoing method embodiments, and details will not be repeated herein. It should be understood that the protection scope of the present disclosure is not limited thereto. Any person skilled in the art can easily think of various equivalent modifications or replacements within the technical scope disclosed in the present disclosure, and these modifications or replacements shall fall within the protection scope of the present disclosure.

What is claimed is:

1. A display panel, comprising:
a sub-pixel;
a pixel circuit configured to drive and control the sub-pixel, the pixel circuit comprising a driving transistor and a first switching transistor, a control portion of the driving transistor being electrically connected to a first electrode of the first switching transistor, and control portions of the first switching transistor comprising a first control portion and a second control portion;
a substrate;
a first conductive layer disposed on a side of the substrate, the first conductive layer comprising a first conductor portion;
an active layer disposed on a side of the first conductive layer facing away from the substrate, the active layer comprising a first channel portion, an orthographic projection of the first channel portion on the substrate overlapping an orthographic projection of the first control portion on the substrate, and the first channel portion being electrically connected to the first electrode of the first switching transistor; and
a second conductive layer disposed on a side of the active layer facing away from the substrate, the first control portion and the second control portion being disposed in the second conductive layer,
wherein an orthographic projection of the first conductor portion on the substrate overlaps the orthographic projection of the first channel portion on the substrate, and the first conductor portion is configured to receive a variable voltage signal.

2. The display panel according to claim 1, wherein the active layer further comprises:
a second channel portion connected between the first channel portion and a second electrode of the first switching transistor, an orthographic projection of the second channel portion on the substrate overlapping both an orthographic projection of the second control portion on the substrate and the orthographic projection of the first conductor portion on the substrate.

3. The display panel according to claim 1, wherein the first conductor portion is electrically connected to the first control portion.

4. The display panel according to claim 3, wherein
the second conductive layer comprises a first scanning line extending in a first direction and electrically connected to the first control portion and the second control portion, the first direction being parallel to a plane of the substrate; and
the first conductor portion extends in the first direction and is connected to the first scanning line.

5. The display panel according to claim 4, wherein an orthographic projection of the first scanning line on the substrate overlaps the orthographic projection of the first conductor portion on the substrate, and the first scanning line is connected to the first conductor portion through a first via.

6. The display panel according to claim 5, wherein the display panel comprises a plurality of the pixel circuits arranged in the first direction, an orthographic projection of the first via on the substrate is located between orthographic projections, on the substrate, of two adjacent pixel circuits of the plurality of the pixel circuits along the first direction.

7. The display panel according to claim 3, wherein the pixel circuit further comprises a first transistor, and the active layer further comprises a third channel portion, an orthographic projection of the third channel portion on the substrate overlapping both an orthographic projection of the control portion of the first transistor on the substrate and the orthographic projection of the first conductor portion on the substrate.

8. The display panel according to claim 7, wherein
the second conductive layer comprises a first scanning line extending in a first direction and electrically connected to the first control portion and the second control portion, the first direction being parallel to a plane of the substrate;
the first conductor portion comprises a first sub-segment, a second sub-segment, and a connecting segment that are connected into one piece, an orthographic projection of the first sub-segment on the substrate overlapping the orthographic projection of the first channel portion on the substrate, an orthographic projection of the second sub-segment on the substrate overlapping the orthographic projection of the third channel portion on the substrate, the connecting segment extending in the first direction and having two ends connected to the first sub-segment and the second sub-segment respectively; and
an orthographic projection of the connecting segment on the substrate overlaps an orthographic projection of the first scanning line on the substrate.

9. The display panel according to claim 7, wherein
a second electrode of the first switching transistor is electrically connected to a second electrode of the driving transistor, and a first electrode of the first transistor is configured to receive a data signal; or
the sub-pixel comprises an anode, a second electrode of the first switching transistor is configured to receive a first reset signal, a first electrode of the first transistor is configured to receive a second reset signal, and a second electrode of the first transistor is electrically connected to the anode.

10. The display panel according to claim 3, wherein the first conductor portion comprises a first sub-segment, the orthographic projection of the first channel portion on the substrate being located in an orthographic projection of the first sub-segment on the substrate.

11. The display panel according to claim 10, wherein
the first conductor portion comprises a third sub-segment, an orthographic projection of the third sub-segment on the substrate being located outside an orthographic projection of the active layer on the substrate; and
a width of the first sub-segment is greater than a width of the third sub-segment.

12. The display panel according to claim 3, wherein the display panel comprises a plurality of the pixel circuits, and the first conductive layer comprises one or more of the first conductor portions, an orthographic projection of one of the first conductor portions on the substrate overlapping orthographic projections of the first channel portions in the plurality of the pixel circuits on the substrate.

13. The display panel according to claim 3, wherein
the pixel circuit further comprises a second switching transistor, a first electrode of the second switching transistor being electrically connected to the control portion of the driving transistor, and control portions of the second switching transistor comprising a third control portion and a fourth control portion; and
a second electrode of the first switching transistor is electrically connected to a second electrode of the driving transistor, and a second electrode of the second switching transistor is configured to receive a first reset signal; or a second electrode of the second switching transistor is electrically connected to a first electrode of the driving transistor, and a second electrode of the first switching transistor is configured to receive a first reset signal.

14. The display panel according to claim 13, wherein
the active layer further comprises a fourth channel portion, an orthographic projection of the fourth channel portion on the substrate overlapping an orthographic projection of the third control portion on the substrate, and the fourth channel portion being electrically connected to the first electrode of the second switching transistor; and
the first conductive layer further comprises a second conductor portion, an orthographic projection of the second conductor portion on the substrate overlapping an orthographic projection of the fourth channel portion on the substrate, and the second conductor portion being electrically connected to the third control portion and being insulated from the first conductor portion.

15. The display panel according to claim 3, wherein the first conductive layer further comprises a third conductor portion, an orthographic projection of the third conductor portion on the substrate overlapping an orthographic projection of the control portion of the driving transistor on the substrate, and the third conductor portion being electrically connected to the control portion of the driving transistor.

16. The display panel according to claim 1, wherein the first conductor portion is electrically connected to the control portion of the driving transistor.

17. The display panel according to claim 16, wherein the first conductive layer comprises a third conductor portion, an orthographic projection of the third conductor portion on the substrate overlapping an orthographic projection of the control portion of the driving transistor on the substrate, and the third conductor portion being electrically connected to the control portion of the driving transistor.

18. The display panel according to claim 17, wherein the first conductive layer further comprises a connecting portion, to which the first conductor portion, the third conductor portion, and the first electrode of the first switching transistor are all electrically connected.

19. The display panel according to claim 16, wherein
the pixel circuit further comprises a second switching transistor, a first electrode of the second switching transistor being electrically connected to the control portion of the driving transistor, control portions of the second switching transistor comprising a third control portion and a fourth control portion; and
a second electrode of the first switching transistor is electrically connected to a first electrode of the driving transistor, and a second electrode of the second switching transistor is configured to receive a first reset signal; or a second electrode of the second switching transistor is electrically connected to a second electrode of the driving transistor, and a second electrode of the first switching transistor is configured to receive a first reset signal.

20. A display device, comprising a display panel,
wherein the display panel comprises:
a sub-pixel;
a pixel circuit configured to drive and control the sub-pixel, the pixel circuit comprising a driving transistor and a first switching transistor, a control portion of the driving transistor being electrically connected to a first electrode of the first switching transistor, and control portions of the first switching transistor comprising a first control portion and a second control portion; and
a substrate;
a first conductive layer disposed on a side of the substrate, the first conductive layer comprising a first conductor portion;
an active layer disposed on a side of the first conductive layer facing away from the substrate, the active layer comprising a first channel portion, an orthographic projection of the first channel portion on the substrate overlapping an orthographic projection of the first control portion on the substrate, and the first channel portion being electrically connected to the first electrode of the first switching transistor; and
a second conductive layer disposed on a side of the active layer facing away from the substrate, the first control portion and the second control portion being disposed in the second conductive layer,
wherein an orthographic projection of the first conductor portion on the substrate overlaps the orthographic projection of the first channel portion on the substrate, and the first conductor portion is configured to receive a variable voltage signal.
